(19) United States
(12) Patent Application Publication
(10) Pub. No.: US 2009/0189272 A1
(43) Pub. Date: Jul. 30, 2009

(54) Wafer Level Chip Scale Packages Including Redistribution Substrates and Methods of Fabricating the Same

(76) Inventors: Min-hyo Park, Gyeonggi-do (KR); Seung-yong Choi, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/357,279

(22) Filed: Jan. 21, 2009

(30) Foreign Application Priority Data
Jan. 24, 2008 (KR) 10-2008-0007554

(51) Int. Cl. H01L 23/02; H01L 21/50

(52) U.S. Cl. 257/690; 438/108; 257/E23.18; 257/E21.499

(57) ABSTRACT

Provided are wafer level chip scale packages, each having a redistribution substrate in which a pad pitch is improved, and methods of fabricating the same. An exemplary wafer level chip scale package includes a semiconductor chip and a redistribution substrate. The semiconductor chip includes a plurality of pads arranged with a first pitch on a first surface thereof. The redistribution substrate includes a plurality of connection wires arranged with a second pitch, which is greater than the first pitch, on a first surface thereof. The redistribution substrate expands a pad pitch from the first pitch to the second pitch by electrically connecting the pads to the connection wires.

### CROSS-REFERENCES TO RELATED APPLICATIONS

This application claims the benefit of Korean Patent Application No. 10-2008-0007554, filed on Jan. 24, 2008 in the Korean Intellectual Property Office, the disclosure of which is incorporated herein in its entirety by reference.

### BACKGROUND OF THE INVENTION

1. Field of the Invention

The present invention relates to semiconductor packages and methods of fabricating the same, and more particularly, to wafer level chip scale packages, each having a redistribution substrate in which a pad pitch of a semiconductor chip is improved, and methods of fabricating the same.

2. Description of the Related Art

With the trend toward more miniaturized, lightweight, and multifunction electronic devices, the demand of high density semiconductor packages has increased. There are chip scale packages, each of which is a completed package having a size close to a chip mounted in the package. The chip scale package maintains a bare chip characteristic in a package state and is greatly reduced in size and is readily handled. The chip scale package has an advantage in size, and has drawbacks in that it is difficult to ensure reliability compared to a conventional package and fabrication cost is high. Thus, a wafer level chip scale package in which an integrated circuit package is formed before cutting a wafer into individual chips has been introduced.

The wafer level chip scale package has a simple manufacturing process since the wafer is packaged in a wafer state, and then cut into individual chips, and the size of the wafer level chip scale package can be reduced. However, with the reduction of the size of the wafer level chip scale package, a pitch between pads is also reduced, resulting in poor contact, thereby reducing reliability of the semiconductor package.

### BRIEF SUMMARY OF THE INVENTION

To address the above and/or other problems, the present invention provides wafer level chip scale packages, each having a redistribution substrate in which a pitch between chip pads is improved, and methods of fabricating the same.

According to an aspect of the present invention, there is provided a wafer level chip scale package. The wafer level chip scale package includes a semiconductor chip and a redistribution substrate. The semiconductor chip includes a plurality of pads arranged with a first pitch on a first surface thereof. The redistribution substrate includes a plurality of connection wires arranged with a second pitch, which is greater than the first pitch, on a first surface thereof. The redistribution substrate expands a pad pitch from the first pitch to the second pitch by electrically connecting the pads to the connection wires.

The redistribution substrate may further comprise a substrate member having a plurality of through holes arranged around the semiconductor chip with the second pitch. The connection wires may have first portions disposed in the through holes, and second portions arranged on a first surface of the substrate and extending to the pads. The first portions of the connection wires, which are disposed in the through holes, may be exposed on a second surface of the substrate member. The substrate member may comprise an insulating substrate comprising a ceramic material and/or an organic material. Each of the connection wires may comprise a first conductive pattern that is formed on the first surface of the substrate member with a first portion disposed in the through hole and a second portion extending to a pad, and a second conductive pattern formed on the first conductive pattern.

The first surface of the semiconductor chip may be arranged to face the first surface of the redistribution substrate, and stud bumps formed on the pads may be flip-chip bonded with the connection wires. Also, the pads of the semiconductor chip may be electrically connected to the connection wires of the redistribution substrate through wires. An underfill material may be disposed between the semiconductor chip and the redistribution substrate to surround the joined units (e.g., joints) of the stud bumps and the connection wires. A sealing member may be formed on the redistribution substrate to cover the semiconductor chip and the connection wires.

According to an aspect of the present invention, there is provided a method of fabricating a wafer level chip scale package. A plurality of semiconductor chips and a mother redistribution substrate are assembled together. Each semiconductor chip has a plurality of pads disposed on a first surface thereof and arranged with a first pitch. The mother redistribution substrate has a plurality of connection wires for each semiconductor chip, with each plurality of connection wires being disposed on a first surface of the mother redistribution substrate and arranged with a second pitch that is greater than the first pitch. The pads of the semiconductor chips are electrically connected to the connection wires of the mother redistribution substrate. A mother sealing member on the mother redistribution substrate is formed to cover the semiconductor chips and the connection wires. The mother redistribution substrate and the mother sealing member are cut into individual wafer level chip scale packages.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-sectional view of a wafer level chip scale package according to an exemplary embodiment of the present invent;

FIG. 1B is a plan view of a wafer level chip scale package according to an exemplary embodiment of the present invention;

FIG. 2 is a cross-sectional view of a wafer level chip scale package according to another exemplary embodiment of the present invention;

FIGS. 3A through 3F are cross-sectional views for explaining a method of fabricating the wafer level chip scale package of FIG. 1a, according to an exemplary embodiment of the present invention;

FIGS. 4A through 4F are cross-sectional views for explaining a method of fabricating the wafer level chip scale package of FIG. 2, according to another exemplary embodiment of the present invention;

FIG. 5 is a cross-sectional view of a wafer level chip scale package according to another exemplary embodiment of the present invention; and

FIG. 6 is a cross-sectional view of a wafer level chip scale package according to another exemplary embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

It will be understood that when a layer is referred to as being “on” another layer or substrate, it can be directly on the other layer or substrate, or intervening layers may also be present. In the drawings, the thicknesses and sizes of layers and regions are exaggerated for clarity, and like reference numerals in the drawings denote like elements. It will also be understood that when an element, such as a layer, a region, or a substrate, is referred to as being disposed “on,” “connected to,” “electrically connected to,” “coupled to,” or “electrically coupled to” another element, it may be directly on, connected to, or coupled to the other element, or one or more intervening elements may be present. In contrast, when an element is referred to as being disposed “directly on,” “directly connected to” or “directly coupled to” another element or layer, there are no intervening elements or layers present. The term “and/or” used herein includes any and all combinations of one or more of the associated listed items.

The terms used herein are for illustrative purposes of the present invention only and should not be construed to limit the meaning or the scope of the present invention. As used in this specification, a singular form may, unless definitely indicating a particular case in terms of the context, include a plural form. Also, the expressions “comprise” and/or “comprising” used in this specification neither define the mentioned shapes, numbers, steps, actions, operations, members, elements, and/or groups of these, nor exclude the presence or addition of one or more other different shapes, numbers, steps, operations, members, elements, and/or groups of these, or addition of these. Spatially relative terms, such as “over,” “above,” “upper,” “under,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device (e.g., package) in use or operation in addition to the orientation depicted in the figures. For example, if the device in the figures is turned over, elements described as “below” or “beneath” or “under” other elements or features would then be oriented “over” or “above” the other elements or features. Thus, the exemplary term “above” may encompass both an above and below orientation.

As used herein, terms such as “first,” “second,” etc. are used to describe various members, components, regions, layers, and/or portions. However, it is obvious that the members, components, regions, layers, and/or portions should not be defined by these terms. The terms are used only for distinguishing one member, component, region, layer, or portion from another member, component, region, layer, or portion. Thus, a first member, component, region, layer, or portion which will be described may also refer to a second member, component, region, layer, or portion, without departing from the scope of the present invention.

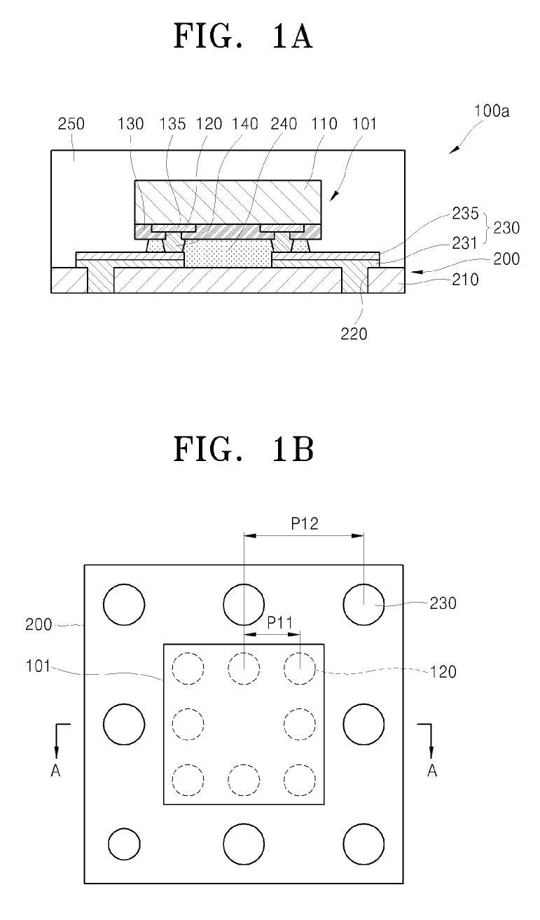

FIG. 1A is a cross-sectional view of a wafer level chip scale package 100a according to an embodiment of the present invention. FIG. 1B is a plan view of the wafer level chip scale package 100a of FIG. 1A. FIG. 1A is a cross-sectional view taken along line A-A of FIG. 1B. Referring to FIGS. 1A and 1B, the wafer level chip scale package 100a includes a semiconductor chip 101 on which a plurality of pads 120 are arranged with a first pitch P11 and a redistribution substrate 200 on which a plurality of connection wires 230 are arranged with a second pitch P12. The second pitch P12 between the connection wires 230 on the redistribution substrate 200 is greater than the first pitch P11 between the pads 120 on the semiconductor chip 101.

The semiconductor chip 101 includes a semiconductor substrate 110 on which integrated circuit devices (not shown) and the pads 120 are formed on a surface thereof. The pads 120 are arranged with the first pitch P11 on the surface of the semiconductor substrate 110. An insulating film 130 is disposed (e.g., formed) on the semiconductor substrate 110 and portions of the pads 120, and includes a plurality of openings 135 that expose a central portion of each of the pads 120. The semiconductor chip 101 further includes a plurality of stud bumps 140 that electrically connect the connection wires 230 of the redistribution substrate 200 to the pads 120 and are arranged on the pads 120 that are exposed by the openings 135.

The redistribution substrate 200 includes a substrate member 210 having a plurality of through holes 220 arranged with the second pitch P12 and portions of the connection wires 230 buried in the through holes 220. Specifically, first portions of the connection wires 230 are disposed in the through holes 220 and are arranged with the second pitch P12. Second portions of the connections wires 230 are formed on a surface of the substrate member 210 and extend to corresponding pads 120 in order to be electrically connected to the pads 120 of the semiconductor chip 101 and to provide the redistribution of the pad pitches. The stud bumps 140 of the semiconductor chip 101 are in electrical contact with second portions of the connection wires 230 of the redistribution substrate 200 by arranging a surface of the semiconductor chip 101 to face the surface of the redistribution substrate 200.

The pads 120 arranged with the first pitch P11 on the semiconductor chip 101 are in electrical contact with the connection wires 230 arranged with the second pitch P12, which is greater than the first pitch P11, on the redistribution substrate 200. As a result, a pad pitch of the wafer level chip scale package 100a to be connected to external terminals is the second pitch P12 which is greater than the first pitch P11 of the semiconductor chip 101. FIG. 1B is a plan view of the bottom surface of substrate 200, which is opposite to the top surface where the semiconductor substrate 100 is disposed. FIG. 1B shows the first portions of the connection wires 230, as exposed through the through holes 220. For reference, FIG. 1B shows the outline of semiconductor chip 101 and the center portions of the pads 120 of semiconductor chip 101. As stated above, the center portions of the pads 120 are exposed through the openings 135 in the insulating film 130.

The stud bumps 140 may include a metal bump comprising Au or Cu. The substrate member 210 may comprise an insulating substrate formed of an organic material and/or a ceramic material. Each of the connection wires 230 may include a first conductive pattern 231 that has a first portion disposed in the through hole 220 and a second portion formed on the substrate member 210 to extend to the pad 120, and a second conductive pattern 235 disposed on the first conductive pattern 231. The first conductive pattern 231 may include a metal pattern comprising, for example, Cu and the second conductive pattern 235 may include a metal pattern comprising, for example, Au.

The wafer level chip scale package 100a may further include an underfill material 240 that is disposed (e.g., buried) between the redistribution substrate 200 and the semiconductor chip 101 to cover joining units of the stud bumps 140 and the connection wires 230. The underfill material 240 increases an adhesion between the stud bumps 140 and the connection wires 230 to prevent a contact failure by increasing an adhesion force therebetween. The wafer level chip scale package 100a may further include a sealing member 250 arranged on the redistribution substrate 200 to cover the semiconductor chip 101, the connection wires 230, and the underfill material 240. The sealing member 250 may include an epoxy molding compound.

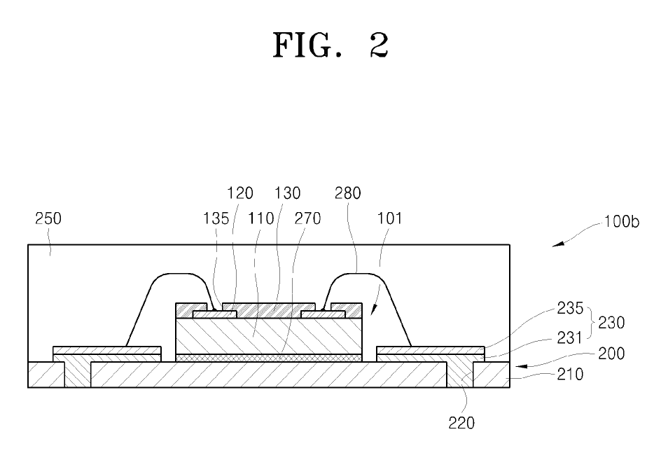

FIG. 2 is a cross-sectional view of a wafer level chip scale package 100b according to another embodiment of the present invention. FIG. 2 is a cross-sectional view corresponding to line A-A of FIG. 1B. Referring to FIG. 2, the wafer level chip scale package 100b includes a semiconductor chip 101 on which a plurality of pads 120 are arranged with a first pitch P11 and a redistribution substrate 200 on which a plurality of connection wires 230 are arranged with a second pitch P12. The second pitch P12 between the connection wires 230 on the redistribution substrate 200 is greater than the first pitch P11 between the pads 120 on the semiconductor chip 101.

The semiconductor chip 101 is mounted on a first surface of the redistribution substrate 200 using an adhesive 270. A portion of each of the pads 120 is exposed through a corresponding opening 135 that is formed in insulating film 130. A substrate member 210 of the redistribution substrate 200 includes a plurality of through holes 220 arranged with the second pitch P12. Portions of the connection wires 230 are buried in the through holes 220 (i.e., pass through the through holes) to be redistributed on the substrate member 210, in a similar manner to that for the previously described embodiment. Portions of the pads 120 are electrically connected to the connection wires 230 via wires 280. The wafer level chip scale package 100b may further include a sealing member 250 arranged on the redistribution substrate 200 to cover the semiconductor chip 101, the wires 280, and the connection wires 230.

The pads 120 of the semiconductor chip 101 are arranged with the first pitch P11, and are electrically connected to the connection wires 230 having the second pitch P12 on the redistribution substrate 200 via the wires 280. Thus, a pad pitch of the wafer level chip scale package 100b to be connected to external terminals is the second pitch P12, which is greater than the first pitch P11, without increasing the size of the semiconductor chip 101.

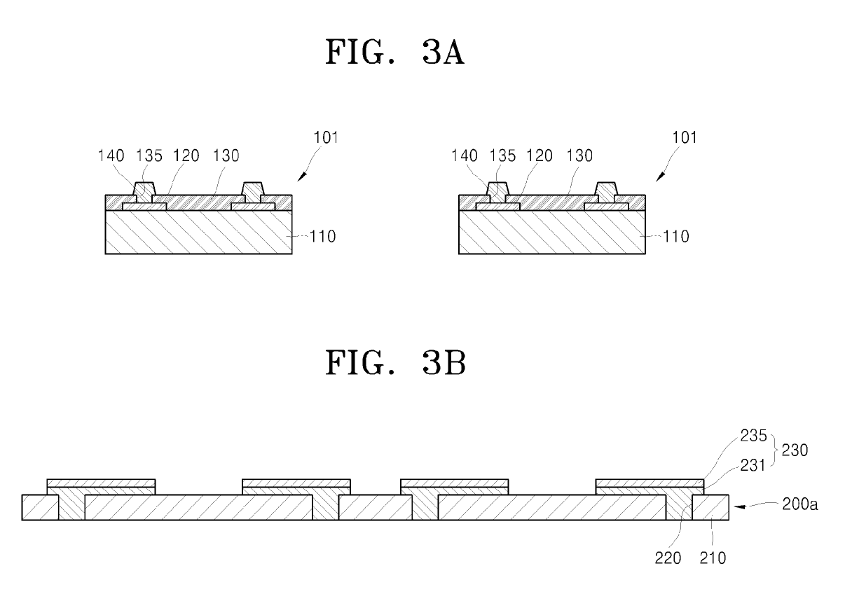

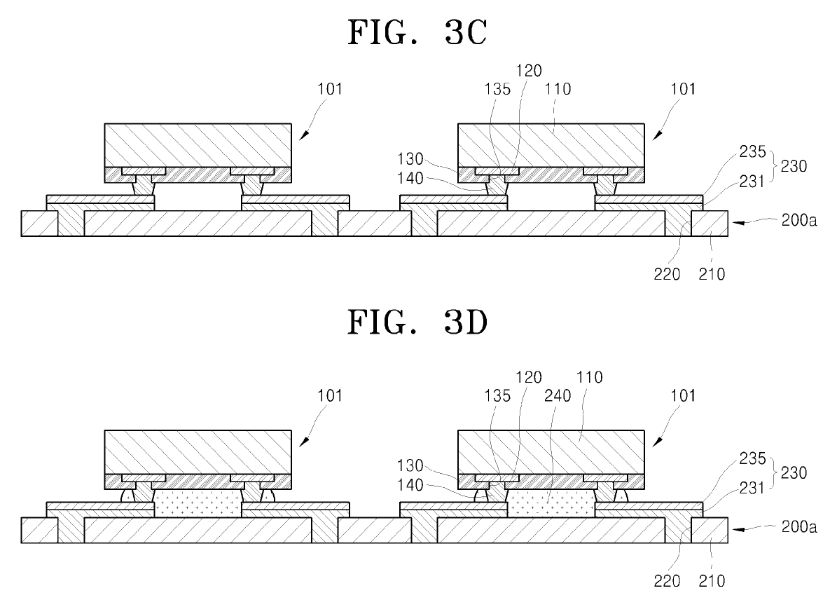

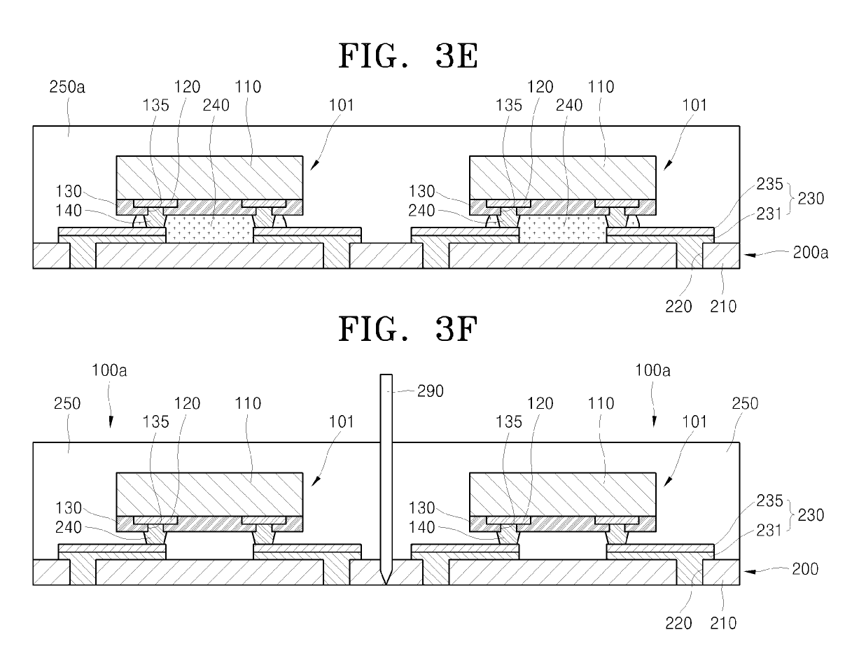

FIGS. 3A through 3F are cross-sectional views for explaining a method of fabricating the wafer level chip scale package 100a according to an exemplary embodiment of the present invention. Referring to FIG. 3A, a plurality of semiconductor chips 101 are prepared. Each of the semiconductor chips 101 includes a semiconductor substrate 110, a plurality of pads 120, and a plurality of stud bumps 140. The pads 120 are arranged with a first pitch P11 on a first surface of the semiconductor substrate 110. An insulating film 130 is formed on the pads 120 and the first surface of the semiconductor substrate 110. The insulating film 130 includes a plurality of openings 135 that expose a portion of each of the pads 120. The stud bumps 140 are arranged on the pads 120 exposed by the openings 135.

Referring to FIG. 3B, a mother redistribution substrate 200a on which the semiconductor chips 101 are mounted is prepared. The mother redistribution substrate 200a includes a substrate member 210 and a plurality of through holes 220 arranged on the substrate member 210. The through holes 220 are arranged with a second pitch P12 around chip regions of the substrate member 210 where the semiconductor chips 101 are mounted. A plurality of connection wires 230, which have first portions disposed (e.g., buried) in the through holes 220 and second portions that extend to the chip regions, are formed on the substrate member 210. Each of the connection wires 230 includes a first conductive pattern 231 that has a portion buried in a through hole 220 and a second portion that extends to the chip region, and a second conductive pattern 235 formed on the first conductive pattern 231. The connection wires 230 are arranged with the second pitch P12 which is greater than the first pitch P11.

Referring to FIG. 3C, first surfaces of the semiconductor chips 101 are disposed to face a first surface of the mother redistribution substrate 200a to electrically contact the stud bumps 140 on the semiconductor chips 101 to the connection wires 230 of the mother redistribution substrate 200a. Next, the stud bumps 140 and the connection wires 230 are bonded through an ultrasonic flip-chip bonding process. Referring to FIG. 3D, in order to increase adhesion force between the stud bumps 140 of the semiconductor chips 101 and the connection wires 230 on the mother redistribution substrate 200a, an underfill material 240 is disposed (e.g., buried) between the semiconductor chips 101 and the mother redistribution substrate 200a to cover the joint units (e.g., joints) of the stud bumps 140 and the connection wires 230.

Referring to FIGS. 3E and 3F, a mother sealing member 250a is formed on the substrate member 210 of the mother redistribution substrate 200a to cover the semiconductor chips 101, the underfill material 240, and the connection wires 230 through an epoxy molding process. Next, the mother sealing member 250a and the substrate member 210 of the mother redistribution substrate 200a are cut into individual wafer level chip scale packages 100a of FIG. 1A using a blade 290 or a laser.

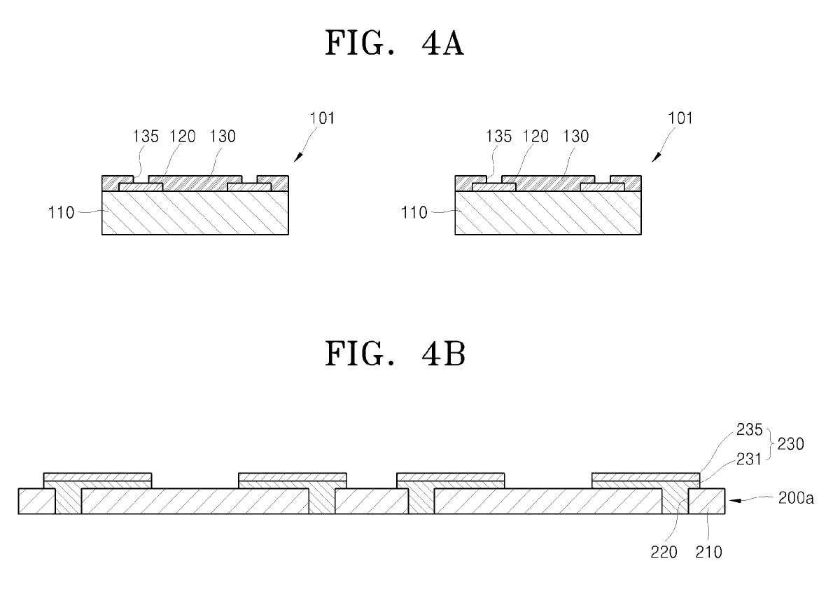

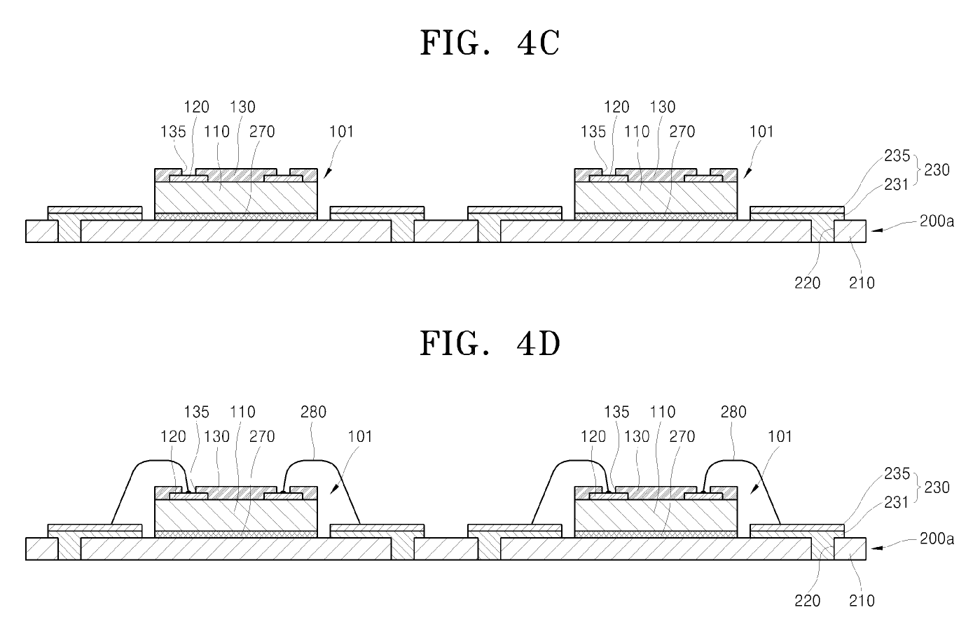

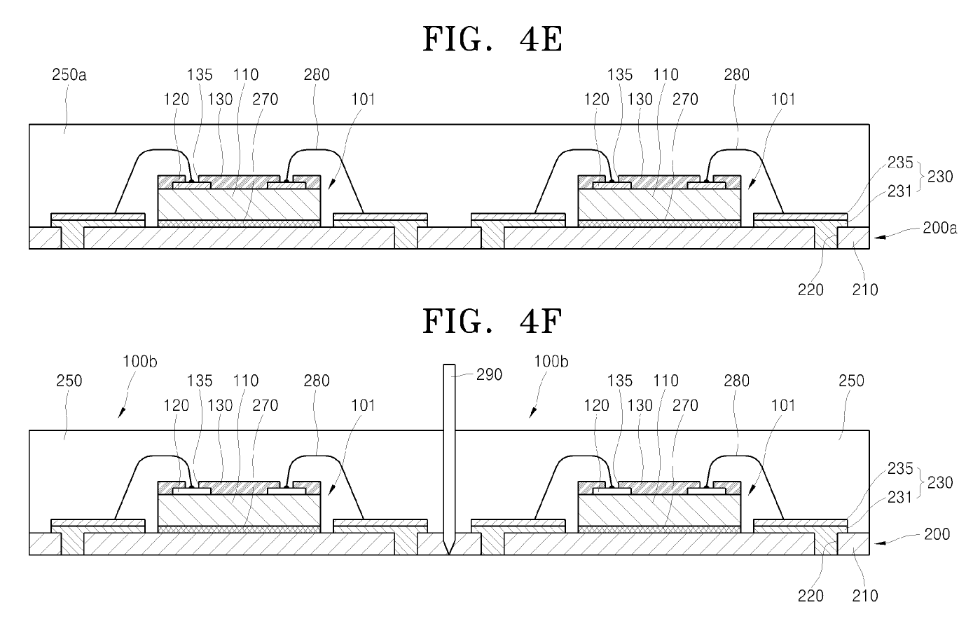

FIGS. 4A through 4F are cross-sectional views for explaining a method of fabricating the wafer level chip scale package 100b of FIG. 2, according to another embodiment of the present invention. Referring to FIG. 4A, a plurality of semiconductor chips 101 are prepared. Each of the semiconductor chips 101 includes a semiconductor substrate 110 and a plurality of pads 120. The pads 120 are arranged with a first pitch P11 on a first surface of the semiconductor substrate 110. An insulating film 130 is formed on the pads 120 and the first surface of the semiconductor substrate 110. The insulating film 130 includes a plurality of openings 135 that expose a portion of each of the pads 120.

Referring to FIG. 4B, a mother redistribution substrate 200a on which the semiconductor chips 101 are mounted is prepared. The mother redistribution substrate 200a includes a substrate member 210 and a plurality of through holes 220 arranged with a second pitch P12 on the substrate member 210. The through holes 220 are arranged around chip regions of the substrate member 210 where the semiconductor chips 101 are mounted. A plurality of connection wires 230, which have first portions disposed in the through holes 220 and second portions that extend to the chip regions, are formed on the substrate member 210. Each of the connection wires 230 includes a first conductive pattern 231 that is disposed (e.g., buried) in the through hole 220 and a second portion that is redistributed to the chip region, and a second conductive pattern 235 formed on the first conductive pattern 231. The connection wires 230 are arranged with the second pitch P12 which is greater than the first pitch P11.

Referring to FIG. 4C, the semiconductor chips 101 are mounted on the chip regions of the mother redistribution substrate 200a. The semiconductor chips 101 may be attached to the mother redistribution substrate 200a using adhesives 270. Referring to FIG. 4D, the connection wires 230 of the mother redistribution substrate 200a are electrically connected to the exposed pads 120 of the semiconductor chips 101 via wires 280 bonded by using a wire bonding process.

Referring to FIGS. 4E and 4F, a mother sealing member 250a is formed on the substrate member 210 of the mother redistribution substrate 200a to cover the semiconductor chips 101, the wires 280, and the connection wires 230 through an epoxy molding process. The mother sealing member 250a and the substrate member 210 of the mother redistribution substrate 200a are cut into the individual wafer level chip scale packages 100b of FIG. 2 using a blade 290 or a laser.

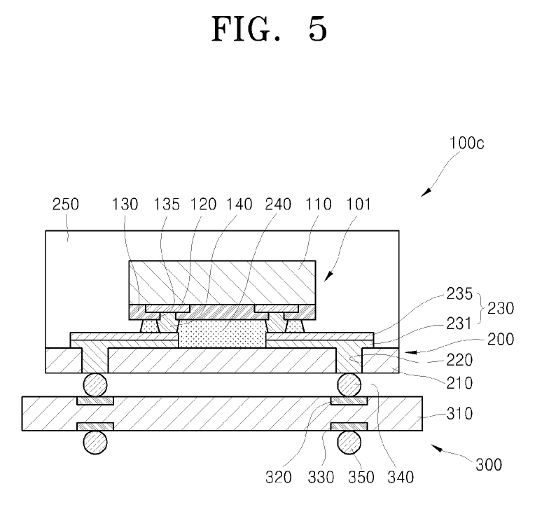

FIG. 5 is a cross-sectional view of a wafer level chip scale package 100c according to another embodiment of the present invention. Referring to FIG. 5, the wafer level chip scale package 100c includes an external connection substrate 300, a redistribution substrate 200, and a semiconductor chip 101 mounted on the redistribution substrate 200. The external connection substrate 300 includes an external substrate member 310, a plurality of first external connection terminals 340, and a plurality of second external connection terminals 350. The external substrate member 310 includes a plurality of first wire patterns 320 arranged on a first surface thereof and a plurality of second wire patterns 330 arranged on a second surface thereof. The external substrate member 310 may be a printed circuit board (PCB). The external substrate member 310 may further include circuit patterns (not shown) for connecting the first wire patterns 320 and the second wire patterns 330 in the external substrate member 310. The first and second external connection terminals 340 and 350 may include solder balls.

The redistribution substrate 200 and the semiconductor chip 101 may have the same structures as the redistribution substrate 200 and the semiconductor chip 101 of FIG. 1A. An underfill material 240 for reinforcing an adhesive force between stud bumps 140 and the connection wires 230 may be filled between the redistribution substrate 200 and the semiconductor chip 101, and a sealing member 250 is formed on the substrate member 210 of the redistribution substrate 200 to cover the connection wires 230, the semiconductor chip 101, and the underfill material 240. On a second surface of the redistribution substrate 200, exposed portions of the connection wires 230 are electrically connected to the first external connection terminals 340 of the external connection substrate 300.

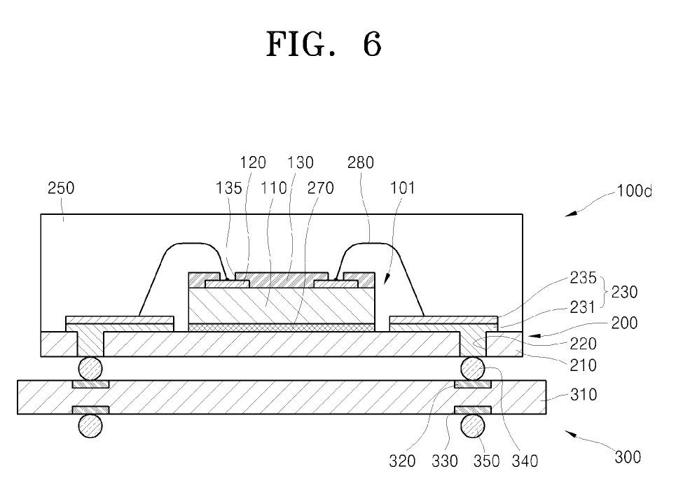

FIG. 6 is a cross-sectional view of a wafer level chip scale package 100d according to another embodiment o the present invention. Referring to FIG. 6, the wafer level chip scale package 100d includes an external connection substrate 300, a redistribution substrate 200, and a semiconductor chip 101 mounted on the redistribution substrate 200. The semiconductor chip 101 is mounted on the redistribution substrate 200 using an adhesive 270, and pads 120 of the semiconductor chip 101 are electrically connected to connection wires 230 of the redistribution substrate 200 via the wires 280. The remaining structure of the wafer level chip scale package 100d is identical to the structure of the wafer level chip scale package 100c of FIG. 5.

In a wafer level chip scale package and a method of fabricating a wafer level chip scale package according to the present invention, after mounting a semiconductor chip having pads arranged with a first pitch on a redistribution substrate having a second pitch greater than the first pitch, the pads of the semiconductor chip are electrically connected to connection wires of a redistribution substrate member having the second pitch greater than the first pitch, and thus, the pad pitch can be improved. A cutting process is performed after mounting semiconductor chips on a redistribution substrate member and performing a molding process, resulting in a fabrication process of the wafer level chip scale package that is simple. Semiconductor chips that are used in a conventional wire bonding package or a flip-chip bonding package can be used without the need for modifications, and thus, a die can be designed in various ways. Furthermore, a package having an improved pitch can be used for mobile products that require a small size of package.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A wafer level chip scale package comprising:
a semiconductor chip having a plurality of pads arranged with a first pitch on a first surface thereof; and
a redistribution substrate that comprises a plurality of connection wires arranged with a second pitch which is greater than the first pitch and expands a pad pitch from the first pitch to the second pitch by electrically connecting the pads to the connection wires.

2. The wafer level chip scale package of claim 1, wherein the redistribution substrate further comprises a substrate member having a plurality of through holes arranged around the semiconductor chip with the second pitch, and
wherein the connection wires have first portions that are disposed in respective ones of the through holes, and second portions that are arranged on a first surface of the substrate member and that extend to the pads, and
wherein the first portions of the connection wires disposed in the through holes are exposed on a second surface of the substrate member.

3. The wafer level chip scale package of claim 2, wherein the substrate member comprises an insulating substrate that includes a ceramic material or an organic material, or both.

4. The wafer level chip scale package of claim 2, wherein each of the connection wires comprises:
a first conductive pattern, the first conductive pattern having a first portion disposed in a through hole and a second portion disposed on the first surface of the substrate member, the second portion extending to a pad; and
a second conductive pattern disposed on at least a portion of the first conductive pattern.

5. The wafer level chip scale package of claim 4, wherein the first conductive pattern comprises a metal pattern that includes copper, and the second conductive pattern comprises a metal pattern that includes gold.

6. The wafer level chip scale package of claim 2, further comprising a sealing member formed on the redistribution substrate to cover the semiconductor chip and the connection wires.

7. The wafer level chip scale package of claim 1, wherein the semiconductor chip further comprises:
a semiconductor substrate;
an insulating film that is disposed on the semiconductor substrate, the insulating film having a plurality of openings that expose portions of the pads; and
a plurality of stud bumps disposed on the exposed portions of the pads.

8. The wafer level chip scale package of claim 7, wherein the first surface of the semiconductor chip is arranged to face the first surface of the redistribution substrate so that the stud bumps and the connection wires are flip-chip bonded.

9. The wafer level chip scale package of claim 8, wherein at least one stud bump comprises a metal bump that includes gold or copper.

10. The wafer level chip scale package of claim 8, further comprising an underfill material disposed between the semiconductor chip and the redistribution substrate to surround a plurality of join units of the stud bumps and connection wires.

11. The wafer level chip scale package of claim 2, wherein each semiconductor chip further comprises:
a semiconductor substrate; and
an insulating film that is disposed on the semiconductor substrate, the insulating film having a plurality of openings that expose portions of the pads, and
wherein the pads of the semiconductor chip are electrically connected to the connection wires of the redistribution substrate through wires.

12. The wafer level chip scale package of claim 2, further comprising an external connection substrate having a plurality of wire patterns electrically connected to the portions of the connection wires that are arranged on a first surface of the substrate member and are exposed on a second surface of the substrate member.

13. The wafer level chip scale package of claim 12, wherein the external substrate member comprises a printed circuit board (PCB).

14. A method of fabricating a wafer level chip scale package comprising:
assembling a plurality of semiconductor chips and a mother redistribution substrate together, each semiconductor chip having a plurality of pads disposed on a first surface thereof and arranged with a first pitch, the mother redistribution substrate having a plurality of connection wires for each semiconductor chip, each plurality of connection wires being disposed on a first surface of the mother redistribution substrate and arranged with a second pitch that is greater than the first pitch, wherein assembling the plurality of semiconductor chips and the mother redistribution substrate together comprises electrically connecting the pads of the semiconductor chips to the connection wires of the mother redistribution substrate;
forming a mother sealing member on the mother redistribution substrate to cover the semiconductor chips and the connection wires; and
cutting the mother redistribution substrate and the mother sealing member into individual wafer level chip scale packages.

15. The method of claim 14, wherein each of the semiconductor chips further comprises a plurality of stud bumps disposed on the pads, and
wherein electrically connecting the pads of the semiconductor chips to the connection wires of the mother redistribution substrate comprises joining the stud bumps of the semiconductor chips with the connection wires of the mother redistribution substrate by disposing the first surfaces of the semiconductor chips to face the first surface of the mother redistribution substrate.

16. The method of claim 15, wherein joining the stud bumps of the semiconductor chips with the connection wires of the mother redistribution substrate comprises performing at least one ultrasonic flip-chip bonding process.

17. The method of claim 14, wherein assembling the plurality of semiconductor chips and the mother redistribution substrate together further comprises mounting the semiconductor chip on the mother redistribution substrate; and
wherein electrically connecting the pads of the semiconductor chips to the connection wires of the mother redistribution substrate comprises electrically connecting the pads to the connection wires via wires by performing a wire bonding process.

18. The method of claim 14, wherein the redistribution substrate further comprises a substrate member having a plurality of through holes arranged with the second pitch around the semiconductor chip,
wherein the connection wires have first portions that are disposed in respective ones of the through holes, and second portions that are arranged on a first surface of the substrate member and that extend to the pads, and
wherein the first portions of the connection wires disposed in the through holes are exposed on a second surface of the substrate member.

19. The method of claim 18, after performing a cutting process, further comprising electrically connecting the portions of the connection wires exposed on the second surface of the substrate member to a plurality of wire patterns arranged on a first surface of an external connection substrate.

20. The method of claim 19, wherein the external connection substrate comprises a printed-circuit board.
